(19) United States
(12) Patent Application Publication
(10) Pub. No.: US 2025/0390029 A1
(43) Pub. Date: Dec. 25, 2025

(54) ADJUSTER USING TORSIONALLY STIFF COUPLER AND ACTUATOR SYSTEM USING SAME

(71) Applicant: Cymer, LLC, San Diego, CA (US)

(72) Inventor: Ian Roger Oliver, Escondido, CA (US)

(21) Appl. No.: 18/877,706

(22) PCT Filed: Sep. 23, 2023
(86) PCT No.: PCT/US2023/033553

§ 371 Date: Dec. 20, 2024

Related U.S. Application Data
(60) Provisional application No. 63/410,025, filed on Sep. 26, 2022.
(60) Provisional application No. 63/426,985, filed on Nov. 21, 2022.

(51) Int. Cl. G03F 7/00

(52) U.S. Cl. CPC G03F 7/70825; G03F 7/70975

(57) ABSTRACT

Disclosed is an apparatus for adjusting the position or orientation of an internal component across a pressurized wall in a system scaled to contain a controlled internal environment, wherein a through-the-wall adjuster projecting out of the system through the pressurized wall includes a concertinaed connector. Also disclosed is a lithographic apparatus including the through-the-wall adjuster. Also disclosed is an apparatus for adjusting the position or orientation of an internal component across a pressurized wall in a system sealed to contain a controlled internal environment, wherein rotation around a first axis of part of a through-the-wall adjuster projecting out of the system through the pressurized wall results in rotation about a different axis inside the sealed system through the use of a concertinaed coupling element.

### CROSS-REFERENCE TO RELATED APPLICATIONS

This application claims priority of U.S. application 63/410,025 which was filed on 26 Sep. 2022 and U.S. application 63/426,985 which was filed on 21 Nov. 2022, each of which is incorporated herein in its entirety by reference.

### TECHNICAL FIELD

The disclosed subject matter relates to systems in which the positions or orientations of elements in an enclosure are adjusted, for example, for alignment or other maintenance purposes, as in some modules of laser-generated light sources used for carrying out photolithographic integrated circuit manufacturing processes.

### BACKGROUND

Components in some systems are maintained in sealed environments. The environment may be sealed, for example, to maintain a desired condition inside the sealed environment such as gas pressure or purity. The sealed environment may also be used to maintain a desired gas composition, such as an inert gas or a purge gas.

It is sometimes necessary in these systems to maintain, e.g., align, components that are situated in the sealed environment. One way to accomplish this is to open the enclosure containing the sealed environment, perform the desired maintenance activity, and then re-seal the enclosure and restore the desired conditions inside the enclosure. Depending on the specific procedure and arrangement, this process may incur substantial amounts of system downtime and contaminate the system. The system may also produce hazardous radiation and it is therefore highly desirable to have a sealed enclosure when the system is necessarily operated during alignment and maintenance adjustments. The overall process of servicing components in a sealed environment can be expedited to the extent it can be performed in-system, that is, without first unsealing and then resealing and restoring the internal environment in the enclosure. It is in this context that the need for the disclosed subject matter arises.

### SUMMARY

The following presents a succinct summary of one or more embodiments in order to provide a basic understanding of the presently disclosed subject matter. This summary is not an extensive overview of all contemplated embodiments and is not intended to identify key or critical elements of all embodiments nor delineate the scope of any or all embodiments. Its sole purpose is to present some concepts of one or more embodiments in a streamlined form as a prelude to the more detailed description that is presented later.

According to one aspect of an embodiment, there is disclosed an optical element alignment mechanism comprising a guide with an arcuate channel, the arcuate channel a having a first channel end and a second channel end, a torsionally stiff elongate member at least partially positioned in the arcuate channel to bend in an arc conforming to an interior of the arcuate channel, the torsionally stiff elongate member having a first end rotatable in a first plane and a second end rotatable in a second plane substantially orthogonal to the first plane, a first mechanical coupling member coupled to the first end, and a second mechanical coupling member coupled to the second end, whereby rotation of the first mechanical coupling member in the first plane causes rotation of the second coupling member in the second plane.

The first mechanical coupling member may comprise a receptacle member for torsional actuation. The second mechanical coupling member may comprise a protrusion for torsional actuation. The torsionally stiff elongate member may comprise an electroformed bellows, wherein the bellows is flexible in degrees of freedom other than axial rotation. The torsionally stiff elongate member may comprise a high strength nickel alloy. The nickel alloy may include copper.

The surface of the torsionally stiff elongate member may be plated. The guide may comprise leaded brass. The guide may comprise leaded bronze. The guide may comprise an alloy which is substantially free of lead. The guide may comprise a first material comprising a pure metal or metallic alloy and the first and second mechanical coupling members may comprise a second material that is substantially dissimilar to the first material.

The torsionally stiff elongate member may have a substantially circular cross section and the arcuate channel may have a substantially semicircular cross section. The torsionally stiff elongate member may have a length in a range of about 15 mm to about 40 mm. The torsionally stiff elongate member may have a diameter in a range of about 5 mm to about 10 mm. The torsionally stiff elongate member may have a radius of curvature in a range of about 10 mm to about 25 mm. The arcuate channel may be open along at least part of an arc length of the arcuate channel.

According to another aspect of an embodiment, there is disclosed a lithographic apparatus comprising an optical pulse stretcher including an enclosure adapted to contain a sealed and pressurized environment and including a wall, the wall having a through-the-wall adjuster, an optical component positioned in the enclosure, at least one of a position or an orientation of the optical component being adjustable by application of a torque to the optical component in a first plane, an elongate torsionally stiff torque transfer element positioned at least partially in the enclosure and having a first end mechanically coupled to the optical component and a second end mechanically coupled to the through-the-wall adjuster, wherein the elongate torsionally stiff torque transfer element is arranged so that rotation in a second plane by manipulation of the through-the-wall adjuster applies the torque to the optical component in the first plane, the first plane and the second plane being substantially orthogonal.

The elongate torsionally stiff torque transfer element may comprise an electroformed bellows. The electrodeposited bellows may comprise a high strength nickel alloy. The lithographic apparatus may further comprise a guide having an arcuate channel arranged to support and laterally stabilize the elongate torsionally stiff torque transfer element. The elongate torsionally stiff torque transfer element may comprise a nickel alloy and the guide may comprise leaded brass or leaded bronze.

The lithographic apparatus may further comprise an arcuate channel arranged along at least part of a length of the elongate torsionally stiff torque transfer element to limit lateral movement or buckling of the elongate torsionally stiff torque transfer element. The arcuate channel may have an open portion along at least part of the length of the arcuate channel. The arcuate channel and the torsionally stiff torque transfer element may be dimensioned and arranged such that the arcuate channel does not mechanically contact the torsionally stiff torque transfer element along a concertinaed portion of the torsionally stiff torque transfer element.

The elongate torsionally stiff torque transfer element may have a substantially circular cross section and the arcuate channel may have a substantially semicircular cross section with a nominal clearance to the circular cross section of the torsionally stiff torque transfer element. The elongate torsionally stiff torque transfer element may have a length in a range of about 15 mm to about 40 mm. The elongate torsionally stiff torque transfer element may have a diameter in a range of about 5 mm to about 10 mm. The elongate torsionally stiff torque transfer element may have a radius of curvature in a range of about 10 mm to about 25 mm.

The elongate torsionally stiff torque transfer element may comprise a guide having an arcuate channel and a torsionally stiff elongate member partially positioned in the arcuate channel to bend in an arc conforming to an interior of the arcuate channel, the torsionally stiff elongate member having a first end rotatable in the first plane and a second end rotatable in the second plane, the arcuate channel and the torsionally stiff elongate member being spaced apart by a clearance. The torsionally stiff torque transfer element may be substantially free of any lubricant.

The elongate torsionally stiff torque transfer element may contain only metallic or ceramic materials that will not contaminate the enclosure when the elongate torsionally stiff torque transfer element is exposed to scattered or direct deep ultraviolet radiation. The elongate torsionally stiff torque transfer element may comprise a first material and the guide may comprise a second material different from the first metal.

According to another aspect of an embodiment, there is disclosed an apparatus for adjusting an optical component in an optical module, the apparatus comprising a through-the-wall adjuster (TWA) comprising a concertinaed connecting element having a first end and a second end, a first coupling element mechanically coupled to the first end, the first coupling element being adapted to impart a rotational force to adjust the optical component, a second coupling element mechanically coupled to the second end, the second coupling element having an external portion dimensioned and configured to extend to an exterior of the optical module and being externally accessible and rotatable to impart a rotational force to the concertinaed connecting element. The concertinaed connecting element may comprise an electroformed bellows, wherein the bellows is flexible in all degrees of freedom other than axial rotation.

The apparatus may further comprise a spherical bearing arranged in the second coupling element to permit rotation of the second coupling element while sealing an interior of the optical module. The spherical bearing may comprise a convex inner ring having a first contour and a concave outer ring having a second contour complementary to the first contour. The outer ring may have a concave inner surface having a second contour complementary to the first contour. The inner ring may comprise a carbon alloy bearing steel. The ring may comprise a ceramic material. The inner ring may comprise a stainless steel. The inner ring may comprise a silicon nitride-alumina composite material. The outer ring may comprise a phosphor bronze alloy material.

The apparatus may further comprise an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator comprising a curved concertinaed coupling element having a first end adapted to rotate around the first axis and a second end adapted to rotate around the second axis. The curved concertinaed coupling element may comprise an electroformed bellows, wherein the bellows is flexible in all degrees of freedom other than axial rotation.

The apparatus may further comprise an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator the actuator may comprise a curved torsionally stiff elongate member positioned in an arcuate channel in a guide, the torsionally stiff elongate member having a first end rotatable around the first axis and a second end rotatable around the second axis, an interior of the arcuate channel and the torsionally stiff elongate member being spaced apart by a clearance.

According to another aspect of an embodiment, there is disclosed a lithographic apparatus comprising an optical pulse stretcher including an enclosure adapted to contain a sealed and pressurized environment and including a wall, an optical component positioned in the enclosure, at least one of a position and an orientation of the optical component being adjustable by application of a torque to the optical component in a first plane, and a through-the-wall adjuster (TWA) comprising a concertinaed connecting element having a first end and a second end, a first coupling element mechanically coupled to the first end, the first coupling element being adapted to impart a rotational force to adjust the optical component, and a second coupling element mechanically coupled to the second end, the second coupling element having an external portion dimensioned and configured to extend to an exterior of the optical module and being externally accessible and rotatable to impart a rotational force to the concertinaed connecting element.

The lithographic concertinaed connecting element may comprise an electroformed bellows, wherein the bellows is flexible in all degrees of freedom other than axial rotation. The TWA may further comprise a spherical bearing arranged in the second coupling element to permit rotation of the second coupling element while limiting an escape of gas and radiation from an interior of the optical module. The spherical bearing may comprise a convex inner ring having a first contour and a concave outer ring having a second contour complementary to the first contour. The outer ring may have a concave inner surface having a second contour complementary to the first contour. The inner ring may comprise a carbon alloy bearing steel. The inner ring may comprise a ceramic material. The inner ring may comprise stainless steel. The inner ring may comprise a silicon nitride-alumina composite material. The outer ring may comprise a phosphor bronze alloy material.

The lithographic apparatus may further comprise an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator including a curved concertinaed coupling element having a first end adapted to rotate around the first axis and a second end adapted to rotate around the second axis. The actuator may comprise a curved torsionally stiff elongate member positioned in an arcuate channel in a guide, the torsionally stiff elongate member having a first end rotatable around the first axis and a second end rotatable around the second axis, an interior of the arcuate channel and the torsionally stiff elongate member being spaced apart by a clearance.

Further embodiments, features, and advantages of the subject matter of the present disclosure, as well as the structure and operation of the various embodiments, are described in detail below with reference to the accompanying drawings.

### DESCRIPTION OF DRAWINGS

The accompanying drawings, which are incorporated herein and form part of the specification, illustrate the presently disclosed subject matter and, together with the description, further serve to explain the principles of the presently disclosed subject matter and to enable a person skilled in the relevant art(s) to make and use the presently disclosed subject matter.

FIG. 1 is a diagram of a photolithography system such as might benefit from implementation of certain aspects of embodiments.

FIG. 2 is a diagram of a light source for a photolithography system such as might benefit from implementation of certain aspects of embodiments.

FIG. 3 is a diagram of an arrangement for in-system adjustment of an optical component in a module for a photolithography system such as might benefit from implementation of certain aspects of embodiments.

FIG. 4A is an isometric view of a coupling system according to an aspect of an embodiment.

FIG. 4B is a front view of the coupling system of FIG. 4A.

FIG. 4C is a front view of a guide component of a coupling system according to an aspect of an embodiment.

FIG. 4D is a front view of a torsionally stiff coupler component for a coupling system according to an aspect of an embodiment.

FIG. 4E is a cutaway view of the coupling system of FIG. 4A.

FIG. 4F is a side diagram of a guide component for a coupling system according to an aspect of an embodiment.

FIG. 4G is a side diagram of a torsionally stiff coupler component for a coupling system according to an aspect of an embodiment.

FIG. 5 is an isometric view of a through-the-wall adjuster (TWA) according to an aspect of an embodiment.

FIG. 6 is a cross-sectional view of the TWA of FIG. 5.

FIGS. 7A, 7B, and 7C are diagrams showing various states of misalignment of a concertinaed connector.

FIG. 8 is a cross-sectional view of a TWA according to an aspect of an embodiment.

FIG. 9 is a cross-sectional view of an actuator system incorporating a TWA and a curved connector according to an aspect of an embodiment.

Further features and advantages of the invention, as well as the structure and operation of various embodiments of the invention, are described in detail below with reference to the accompanying drawings. It is noted that the scope of this disclosure is not limited to the specific embodiments explicitly described herein. Such embodiments are included herein for illustrative purposes only. Additional embodiments will be apparent to persons skilled in the relevant art based on the teachings presented herein.

### DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. This summary is not an extensive overview of all contemplated embodiments and is not intended to identify as key or critical any elements of any embodiments nor delineate the scope of any or all embodiments.

Systems such as those described herein may render benefits in a wide range of applications and implementations. For the sake of having a specific nonlimiting example to facilitate description, one such application is in semiconductor photolithography.

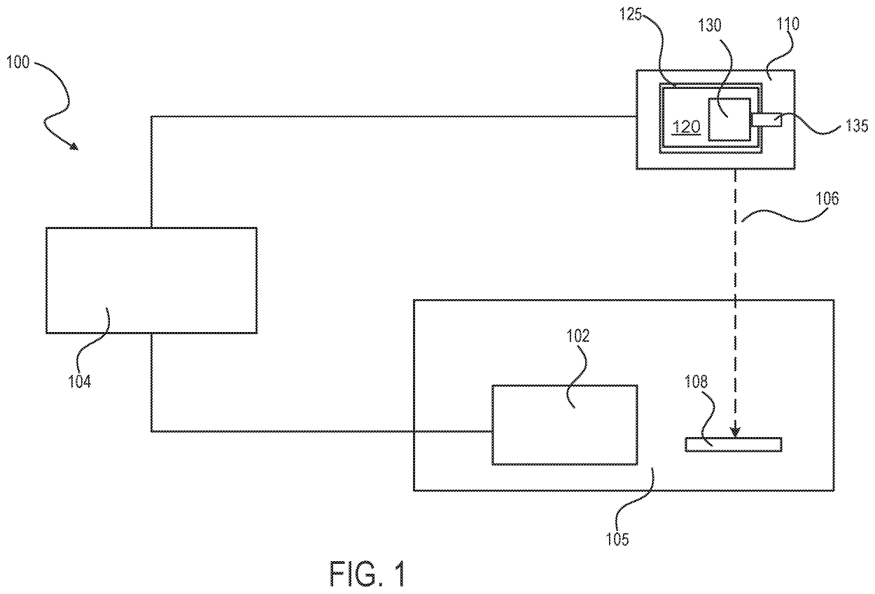

Referring to FIG. 1, an optical system 100 including a system controller 104 and an output apparatus controller 102, is configured with an illumination system 110 that produces a pulsed laser light beam 106. The illumination system 110 is configured with modules including an optical pulse stretcher (“OPuS”) 120. As described in more detail below, the OPUS 120 includes an enclosure 125 that contains a controlled atmosphere. The OPUS enclosure also contains optical components, one of which is shown as optical component 130, that are adjustable using through-the-wall adjusters (“TWAs”) such as TWA 135 that permit adjustment of the internal optical components without having to break containment of the enclosure 125.

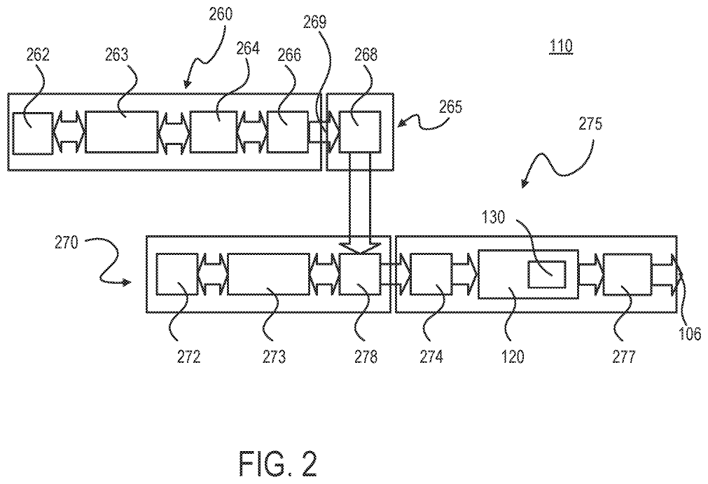

The light beam 106 may be directed to an output apparatus such as a stepper/scanner 105. The stepper/scanner 105 is a photolithography exposure apparatus that patterns microelectronic features on a wafer 108 using the light beam 106. In a photolithography system, the components configured within the illumination system 110 (as shown in FIG. 2), including the OPUS 120 with the optical component 130, will determine the parameters of the light beam 106, and thereby the parameters of the microelectronic features patterned on the wafer 108 by the stepper/scanner 105.

FIG. 2 is a functional block diagram of an example configuration for the illumination system 110 module including the OPUS 120. The light beam 106 produced by the illumination system may be in the deep ultraviolet (DUV) range, for example, a wavelength of 248 nanometers (nm) or 193 nm.

As shown in FIG. 2, the illumination system 110 includes a gas discharge seed laser system 260. The seed laser system 260 is configured to produce the seed laser output pulse from a master oscillator (“MO”) 263. The MO 263 can be configured as a chamber with a pair of electrodes (not shown) such that there is an electrical discharge between the electrodes that causes lasing gas discharge in a lasing gas, for example, ArF, KrF, F₂, and/or XeF, that produces relatively broad band radiation.

The resulting broad band radiation can be modified by a line narrowing module (“LNM”) 262 such that a relatively very narrow bandwidth and center wavelength can be selected. The LNM 262 may include a grating (not shown). A master oscillator output coupler (“MO OC”) 264 receives radiation from the MO 263. The output of the MO OC 264 may be directed to a line-center analysis module (“LAM”) 266 that produces the output 269.

The output 269 propagates to a relay optics system 265. The relay optics system 265 includes a MO wavefront engineering box (“WEB”) 268 and may include a multi-prism beam expander (not shown) and an optical delay path (not shown). The WEB 268 can be used to redirect the output 269 of the seed laser system 260 to a power ring amplification (“PRA”) stage 270.

The PRA stage 270 includes a beam reverser 272, a PRA lasing chamber 273, and a PRA WEB 278. The PRA WEB 278 is arranged to receive the redirected output 269 of the seed laser system 260 from the relay optics system 265 MO WEB 268. The PRA WEB 278 may include a partially reflective input/output coupler (not shown), a maximally reflective mirror for the nominal operating wavelength, and a one or more prisms. The PRA WEB 278 may be provided with seed beam injection and output coupling optics (not shown) such that the beam is redirected through a gain medium within the PRA lasing chamber 273 by the beam reverser 272.

The PRA lasing chamber 273 includes a chamber with a pair of electrodes (not shown). The PRA lasing chamber 273 can produce an electrical discharge between the electrodes and thereby produce broad band radiation.

The output of laser light beam pulses from the PRA stage 270 are directed by the PRA WEB 278 to an output subsystem 275 that measures and modifies the parameters of the laser light beam before producing the illumination systems 110 final light beam 106. The output subsystem 275 includes a bandwidth analysis module (“BAM”) 274 that receives the PRA stage 270 output and extracts a portion of the laser light beam pulses for metrology purposes, for example, to measure the bandwidth or pulse energy. The laser light beam pulses are then passed through the OPUS 120 within the output subsystem 275 to modify the light beam pulses.

The components within the OPUS 120 can be configured to convert a single output pulse into a pulse train. Secondary pulses created from the original single output pulse are delayed with respect to each other such that the effective pulse length of the laser is expanded and the peak pulse intensity is reduced. The resulting light beam from the OPUS 120 is passed through a combined autoshutter metrology module (“CASMM”) 277 or a pulse energy meter within the output subsystem 275 before the light beam 106 is emitted from the illumination system 110.

The light beam propagating through the illumination system 110 is typically at a wavelength that is absorbed by some gaseous components of air. For this reason air is purged from the path that the radiation takes though the modules in the illumination system 110 and replaced with a gas that is more transparent to DUV radiation such as nitrogen. Nitrogen gas provides a substantially lower beam attenuation than air and does not absorb short wavelength light beams like other elements within air such as oxygen.

In addition, the light beam may be adversely affected by contaminants in its path such as may be introduced, for example, by the outgassing of organic lubricants in the modules. For this reason it is desirable to avoid the use of such lubricants for reducing friction between two surfaces when one is moved with respect to the other such as may occur during mechanical manipulation of components within the module.

As mentioned, the optical components that are situated within an enclosure of a module in which a controlled atmosphere is maintained may need to be aligned or otherwise adjusted from time to time. The controlled atmosphere of an enclosure of a module may be at a different pressure than the atmospheric pressure of the surrounding environment external to the enclosure. For example, the pressure of the gas within the enclosure can be five pounds per square inch greater than the atmospheric pressure of the surrounding environment.

Also as mentioned, it is advantageous to be able to make such adjustments without having to unseal and reseal the enclosure, i.e., in-system. To permit such in-system adjustments coupling system is such as TWAs are used which have an external portion. The external portion of the TWAs are accessible by a field service engineer (“FSE”) and are mechanically coupled to an internal portion that is situated in the controlled environment across the pressurized wall of the enclosure.

The FSE manipulates the external portion of the TWA to cause movement (e.g., translational, axial, rotational) of the internal portion. The internal portion is in turn mechanically coupled to the component being adjusted. The net effect is that the FSE can adjust the internal component simply by manipulating an external component without disturbing the environment in the module.

For some arrangements the induced motion may be axial, that is, inward or outward with respect to the enclosure wall along an axis of rotation of the external portion of the TWA. For other arrangements, however, it may be required to relay the torque applied to the external portion of the TWA to an internal component in a plane that is at an angle to the plane of the externally applied torque. Such an arrangement requires the use of a subsystem that can turn the direction of the torque accordingly.

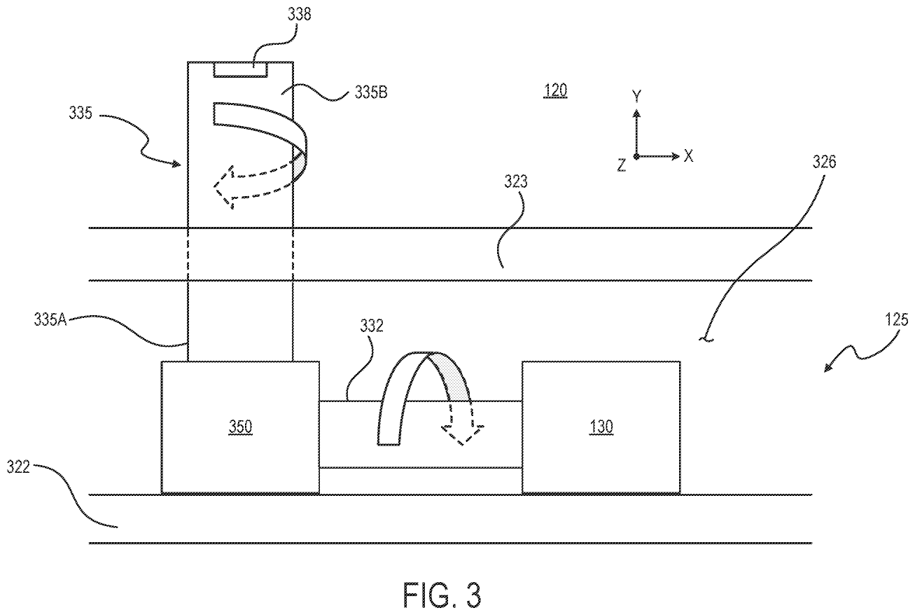

For example, as shown in FIG. 3, an OPUS 120 includes a torque angle converter 350 that is coupled to the optical component 130 by a shaft 332 within an interior 326 of the enclosure 125. It will be understood that that OPUS 120 is being referred to herein merely for the sake of having a concrete example to facilitate the description and that underlying principles apply equally to other modules in the illumination systems 110 as well as to enclosed modules in other systems.

In FIG. 3, the enclosure 125 includes an enclosure wall 323 and enclosure frame 322. The OPUS 120 components including the torque angle converter 350 and the optical component 130 can be mounted and fixed to the enclosure frame 322 within the interior 326. The enclosure 125 is sealed to permit the interior 326 and the components such as the torque angle converter 350 and optical component 130 situated within the enclosure to be maintained within a controlled environment. It will be appreciated that during use the interior 326 will in general be permeated with DUV radiation.

The arrangement of FIG. 3 also includes a TWA 335. The TWA 335 includes an internal end 335A and an external projecting end 335B. The external end 335B may include structure 338 defining a socket which is dimensioned and arranged to receive a mating portion of a tool inserted by the FSE. The internal end 335A of the TWA 335 may be mechanically coupled to a torque angle converter 350 within the sealed enclosure 125.

Rotation of the TWA 335 causes rotation of the shaft 332 through the torque angle converter 350 such that the optical component 130 that is coupled to the shaft 332 is also adjusted. The torque angle converter 350 converts torque applied in one plane to a different plane at a different angle. For example, if FIG. 3 is taken as lying in the X-Y plane, then, if the TWA 335 applies a torque (rotates in) the X-Z plane (i.e., about the Y axis) then the torque angle converter 350 may need to convert the torque to a torque in the Y-Z plane (i.e., about the X axis) to adjust the optical component 130. In the example in FIG. 3, the plane of rotation of the TWA 335 is orthogonal to the plane of rotation of the shaft 332 but a given application may require a re-direction of the torque by an angle other than 90 degrees. Here and elsewhere, torque is used in its conventional sense of a force tending to produce a change in the rotational motion of a body. Inasmuch as the direction of the torque will in general coincide with the direction of the rotation these directions are used interchangeably herein.

One possible implementation of the torque angle converter 350 may include a gearbox which operates in a known manner to produce a rotational motive force in one direction in response to the application of a rotational force in another direction. Gearboxes, however, may be mechanically complicated and require high precision manufacturing tolerances and custom made parts that can increase manufacturing costs. Gearboxes may also experience mechanical failure modes such as galling (adhesive wear) particularly in the absence of lubrication. Lubricants generally cannot be employed in environments such as those involved here to mitigate such mechanical failure modes. This is because lubricants can outgas when exposed to DUV radiation and contaminate the sealed environment in which the gearbox would be located. It would be advantageous to have a mechanism capable of re-directing direct torque without these drawbacks.

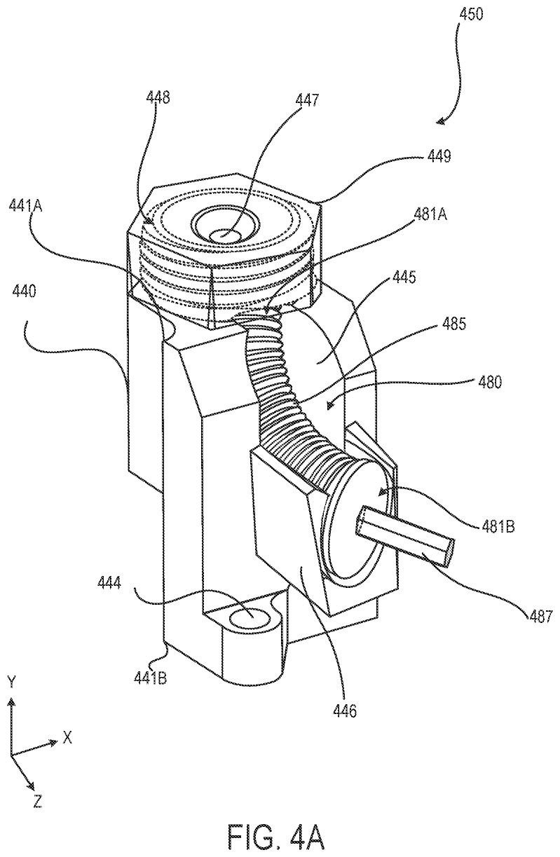

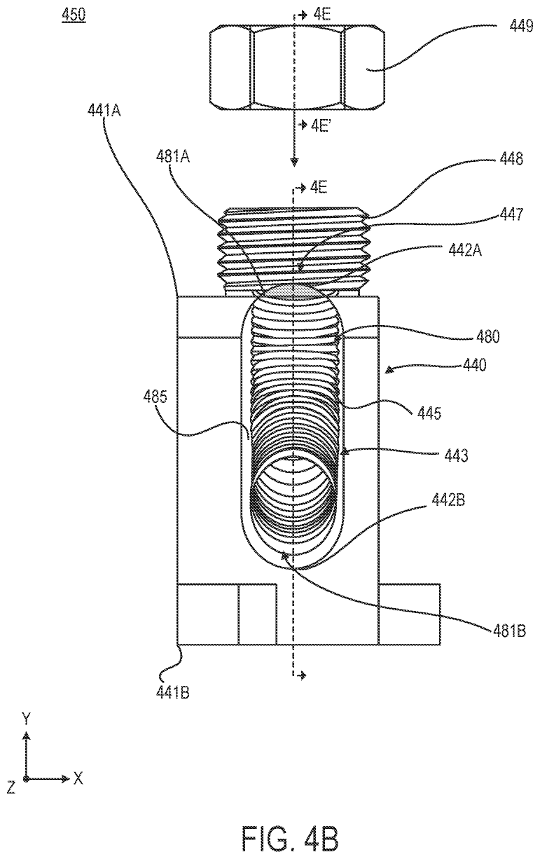

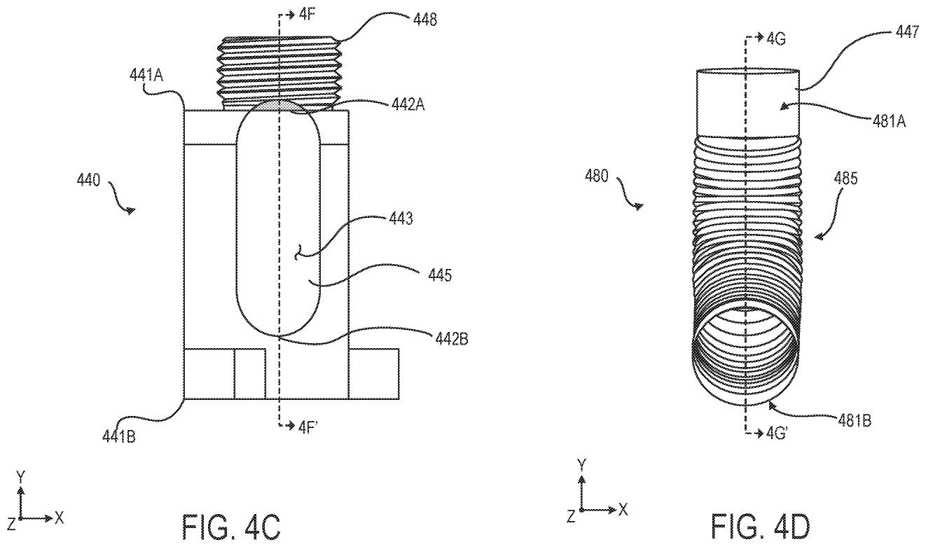

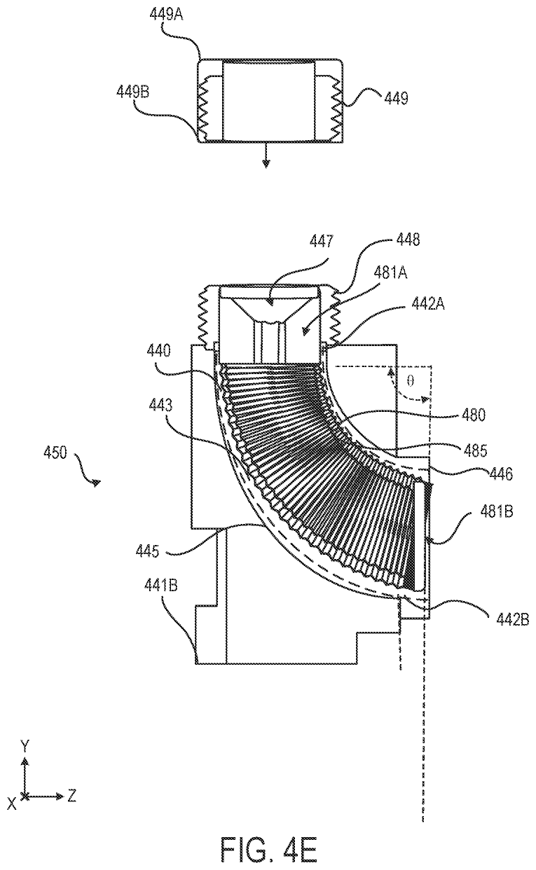

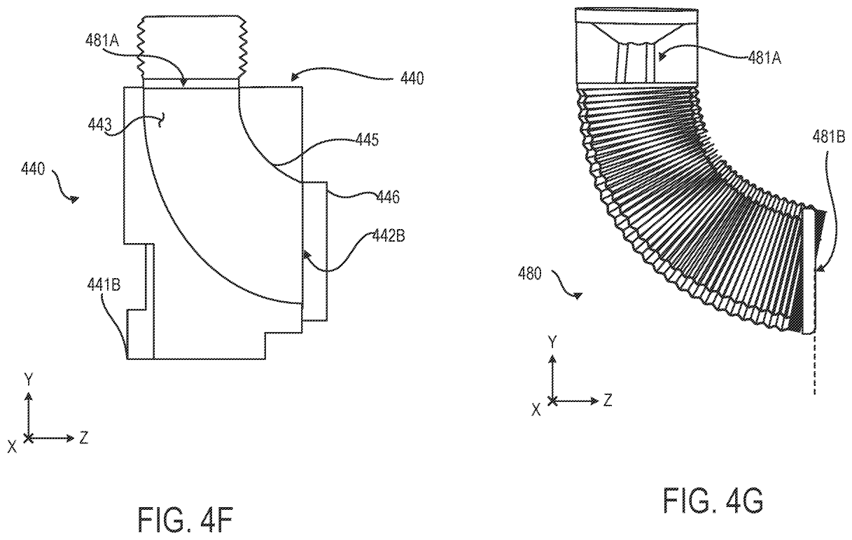

Thus, according to an aspect of an embodiment, a possible implementation of a torque angle converter 450 is shown in FIGS. 4A-4G. The design of the torque angle converter 450 enables high-precision adjustment to be made when mechanically coupled to a TWA such as the TWA 335. The torque angle converter 450 is less expensive to manufacture because some of the components used for the torque angle converter 450 do not need to be custom made and can have lower precision manufacturing tolerances than a gearbox without adversely impacting performance. The torque angle converter 450 may also be designed with contacting surfaces made of dissimilar materials between which mechanical adhesion/galling is less likely to occur. The torque angle converter 450 may be implemented so that it is readily retrofittable into optical systems already deployed in the field, such as a deployed OPUS 120, and may be installed instead of or in addition to gearboxes. The torque angle converter 450 can simply be installed within such deployed optical systems without requiring excessive if any modifications to be made to the optical system.

Referring to FIG. 4A, the torque angle converter 450 includes a guide 440 and a torsionally stiff coupling element (“TSCE”) 480. The guide 440 includes a first end 441A and a second end 441B. The guide 440 also includes structure defining a channel 445 and a guide extension 446 positioned to define an extension of the channel 445. The first end 441A of the guide 440 has an externally threaded mechanical coupling member 448 that mates in a known way with an internally threaded mechanical coupling member 449. The coupling member 448 extends from the first end 441A and has a central opening that is aligned with the channel 445.

The TSCE 480 is made up in part of a concertinaed element 485 with a first end 481A and a second end 481B. The first end 481A can be provided with an end fitting 447, and the second end 481A can be provided with an extending member 487. The end fitting 447 of the TSCE 480 has a socket accessible through the central opening in the coupling member 448. When the coupling member 448 is attached to the coupling member 449, the position of the fitting 447 is fixed with respect to the guide 440. At the same time, the end fitting 447 can be rotated by a TWA inserted into the socket in the end fitting 447, which in turn causes rotation of the TSCE 480. This causes rotation of the extending member 487, which may be coupled, for example, to a component of the optical system to adjust some attribute of that component, e.g., position or degree of rotation.

The guide 440 may further include one or more mounting flanges 444 that can be used to secure the guide 440 to a support within an enclosure or assembly such as the enclosure 125 (FIG. 3).

FIGS. 4B and 4C are front views of the guide 440 with (FIG. 4B) and without (FIG. 4C) the TSCE 480. The first end 441A extends to the second end 441B along the Y-axis. The first end 441A and the second end 441B of the guide 440 define the channel 445 with a guide interior surface 443 including a first end 442A and a second end 442B.

The guide interior surface 443 of the channel 445 is configured and dimensioned such that the channel 445 has an overall arcuate shape (as shown in FIGS. 4E and 4F) corresponding to the shape of the TSCE 480 when the TSCE 480 is in place. The TSCE 480 when installed in its curved configuration has a shorter inner curved side (closer to the radius of curvature in cases where the TSCE 480 is curved in a circular arc) and a longer curved side (farther from the radius of curvature in cases where the TSCE is curved in a circular arc). According to an aspect of the embodiment shown, the channel 445 is open adjacent to the shorter (inner) curved side of the TSCE 480. In other words, the arcuate channel is configured with an open portion along at least part of the arc length of the arcuate channel. It will be appreciated by one of ordinary skill in the art that channel 445 could be configured without an open portion as long as there is an appropriate clearance between the TSCE 480 and the guide interior surface 443 in the area where the open side is shown in the figure.

The arcuate shape of the channel 445 may be chosen such that the first end 442A of the channel 445 is oriented to extend parallel to the Y-axis with the second end 442B being oriented to extend parallel to the Z-axis. The channel 445 can extend between the first and second end 442A and 442B. In the embodiment shown the angle θ between the first and second end 442A and 442B is about 90° thus permitting accommodation of a TSCE that is capable of applying torque at one end in a plane that is orthogonal to the torque applied to the TSCE at its other end.

It will be understood that references to XYZ coordinate frames of reference here and throughout this specification are for the purposes of describing relative positioning and orientation only and not necessarily positioning and orientation with respect to a specific or absolute frame of reference unless the context indicates otherwise. Similarly the use of terms such as up, down, top, bottom, and so on do not necessarily refer to a specific frame of reference unless the context indicates otherwise.

The coupling member 448 at the first end 441A of the guide 440 projects from the first end 441A in the Y direction. The coupling member 449 may be a nut formed to receive an externally threaded member such as the coupling member 448 that can be in the form of a fine-pitched threaded screw.

As mentioned, the concertinaed element 485 may be formed as a bellows curved to have a curved cylindrical form (as shown in FIGS. 4E and 4G). Moreover, a first end 481A of TSCE 480 may be oriented primarily to extend parallel to a Y-axis and a second end 481B of TSCE 480 may be primarily oriented to extend parallel to the Z-axis. The TSCE 480 can be arranged to extend from the first end 481A to the second end 481B. As disclosed below the concertinaed element may be a bellows formed by electrodeposition.

The electrodepositing process may use a machined mandrel, e.g., a mandrel machined out of aluminum. The mandrel is then electroplated and the aluminum mandrel is then dissolved leaving a component made up of the electrodeposited nickel. The resulting component can thus be described as an electroformed plating. The resulting component can tolerate lateral and axial motion, i.e. has various degrees of freedom, yet remain torsionally stiff. The degrees of freedom enable the bellows to tolerate a greater degree of component misalignment, for example, for components oriented orthogonal to one another. Such bellows transmit torque with negligible windup as they bend, compress, and extend. Conventionally such bellows are used for unaligned coupling, i.e., where one end of the bellows is at bent an angle to the other end of the bellows, but only at angles smaller than 90°. In the application contemplated herein, however, the number of manipulations over the anticipated service lifetime of the component is small enough that the bellows can operate with a 90° bend over that lifetime. Such bellows may also be fabricated by a hydroforming technique which uses a specialized type of die molding and highly pressurized fluid to form metal.

The TSCE 480 disclosed is torsionally stiff. It will be understood by one of ordinary skill in the art that the term “torsionally stiff” is intended to have its conventional meaning of minimal elastic windup, backlash, and hysteresis so that rotating one end of the TSCE 480 will result in the other end of the TSCE 480 rotating by substantially the same amount. This rotational fidelity also makes it possible for the mechanism to provide tactile feedback to an FSE or other operator making it possible for the FSE to sense qualitatively an amount of resistance to rotation.

The interior of the guide channel 445 is dimensioned with respect to the concertinaed element 485 such that the interior of the guide channel 445 and a neighboring portion of the exterior of the concertinaed element 485 do not come into contact during normal operation. For parts of the TSCE 480 and the guide 440 that do come into sliding contact it may be advantageous for some applications to make at least the portions that come into contact out of dissimilar metals to prevent galling and adhesive wear, particularly in the absence of oxygen. For example, the TSCE 480 as mentioned may be made of nickel alloy and the guide 440 may be made of leaded brass.

As described, the environment in which the coupling subsystem will be located will in general be bathed in radiation such as DUV radiation. This radiation can cause some materials to outgas and thereby contaminate the controlled environment within the enclosure that houses them. This can interfere with the propagation of a beam of radiation along a path through the enclosure. The optical components may also be damaged if such contaminants come in contact with their surfaces. Under such conditions, the ability to fabricate the coupling subsystem completely out of materials such as metals and ceramics that will not outgas upon exposure to DUV radiation can provide significant advantages.

FIGS. 4E-4G are cross-sectional views of the guide 440 and TSCE 480. FIG. 4E is a cross-sectional side view of the guide 440 and TSCE 480 as seen from the direction indicated by the line 4E-4E′ in FIG. 4B. In FIG. 4F the guide 440 is shown without the TSCE 480 as seen from the direction indicated by the line 4F-4F′ in FIG. 4C, and in FIG. 4F the TSCE 480 is shown separate from the guide 440) as seen from the direction indicated by the line 4G-4G′ in FIG. 4D.

FIGS. 4E-4G show the curvature of the channel 445 and the concertinaed element 485 according to an embodiment. Both the channel 445 and the concertinaed element 485 may extend with a curved shape such that the curvature angle θ is approximately 90°. The length of channel 445 from the first end 442A to the second end 442B may be less than the length of the concertinaed element 485 extending from the first end 481A to the second end 481B which may be, for example, in the range between approximately 15 mm to approximately 40 mm. The portion of the second end 481B of the TSCE 480 may extend primarily in the Z direction beyond the second end 442B of the channel 445 and may be contained within the guide extension 446 that extends from the second end 442B of the channel 445 primarily in the Z direction.

According to another aspect of an embodiment the channel 445 is formed such that its diameter and corresponding radius is larger than the concertinaed element 485 diameter which may, for example, be in the range of approximately 5 mm to approximately 10 mm with a radius of curvature radius which may, for example, be in the range of approximately 10 mm to approximately 25 mm. In normal operation, the TSCE 480 may be rotated without the concertinaed element 485 coming in contact with the channel 445. Additionally, the channel 445 is configured such that lateral movement or buckling of the concertinaed element 485 is avoided. For example, the channel 445 can have a length of 20 mm with the guide extension 446 of 5 mm including a diameter of 10 mm, such that a concertinaed element 485 having a length of 25 mm and diameter of 7 mm may be accommodated within the channel 445.

The TSCE 480 end fitting 447 is retained within the first mechanical member 448 within the channel 445, with the first mechanical member 448 received within the second member 449 outside the channel 445. The end fitting 447 includes a hex receptacle that can be mechanically engaged by a TWA (as shown in FIG. 3) including a hex wrench member to permit rotation of the TSCE 480. The TSCE 480 may thus be configured to convert torque applied by, for example, TWA 335 (FIG. 3) in one plane to a different plane to enable alignment or adjustment of components such as the optical component 130 (FIGS. 1-3).

A conventional TWA uses mating threaded elements that form a type of labyrinthine seal which adequately isolates the environments internal and external to the component housing from one another during alignment procedures. The small clearances between the unlubricated mating threads are sufficient to prevent significant egress of purge gas and laser radiation and to prevent excessive oxygen ingress.

Such a conventional TWA is designed to actuate an internal threaded adjuster, and the threads on each device translate similarly along their axes when rotated clockwise or counterclockwise. The use of a threaded TWA in conjunction with an unthreaded curved bellows actuator as described above can, however, lead to several technical challenges. For example, the adjustment range of the threaded TWA is limited to that which can be accommodated by the thread's range of travel in the mechanism. Careful positioning of the threaded TWA shaft is necessary to achieve even a marginal range of adjustment.

In addition, the tip of the threaded TWA shaft is typically spring loaded and applies an axial force to the bellows end fitting. While the spring force is relatively modest (on the order of 2 lb-f), in practice this load is applied across metal interfaces with a small area of contact, during relative motion, and without lubrication. This generates particles and unnecessary wear and has the potential to cause premature failure.

Also, the existing TWA has axial torsional stiffness to transmit the actuation torque, but not the degrees of freedom (DOF) needed to provide flexibility to minimize loads resulting from any lack of fit due to part and assembly tolerances. In conventional practice this flexibility is provided by generous clearances between parts, and a single (1 DOF) pin joint. The degree of flexibility in these DOFs is therefore mostly an unpredictable and variable function of part manufacturing tolerances.

According to an aspect of an embodiment, the design of the TWA eliminates the need for threaded elements and reduces axial loads on the coupling. It provides five degrees of freedom to accommodate assembly alignment tolerances.

A consequence of avoiding the use of threaded elements is that there is no axial translation of the actuator shaft when the actuator is turned. This means that the design of the TWA need not accommodate any axial translation of the shaft. In other words, there is no imposed range of axial movement which must be accommodated.

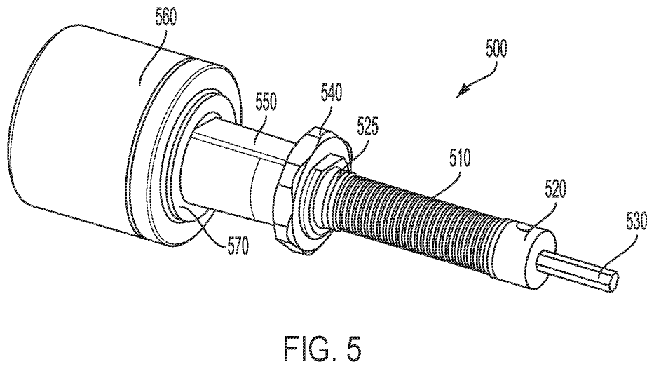

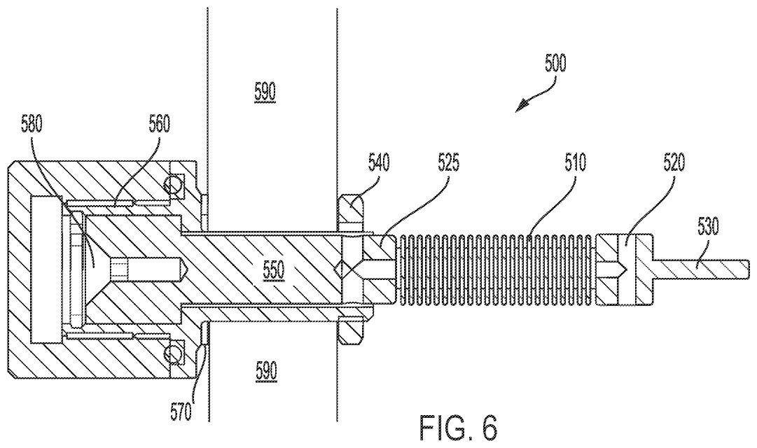

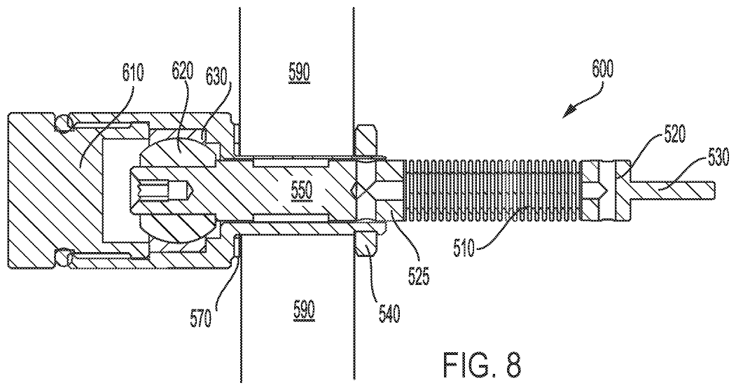

FIG. 5 is an isometric view of a TWA 500 according to an aspect of an embodiment. The TWA 500 includes a concertinaed or corrugated coupler 510 having coupler end pieces 520 and 525. The coupler end piece 520 is provided with a projection 530 which may, for example, have a hexagonal cross section to mate with a corresponding receptacle in a curved coupler as described above. The TWA 500 also includes a shaft portion 550 which extends through the wall of an optical module. Retaining nut 540 secures the TWA 500 to the wall of the optical module. The TWA 500 also includes an external coupler 560 which includes structure 580 (FIG. 6) that someone external to the optical module such as a field service engineer, can use to rotate the coupler 510 disposed inside the optical module. The arrangement also includes a gasket 570 for sealing the TWA 500 to the exterior wall of the optical module such that the wall is accommodated between gasket 570 and retaining nut 540 (see FIG. 8).

FIG. 6 is a cross-sectional view of the TWA 500 of FIG. 5 as it might be installed in a system. Again, the TWA 500 includes the coupler 510 with coupler end pieces 520 and 525. The coupler end piece 520 is provided with the projection 530. The TWA 500 also includes the shaft portion 550 shown as a part of the coupler end piece 525 which extends through a wall 590 of an optical module. Retaining nut 540 secures the TWA 500 to the wall of the optical module. FIG. 6 also shows the structure 580 that a field service engineer can rotate to in turn rotate the coupler 510. The arrangement also includes the gasket 570 for sealing the TWA to the exterior wall of the optical module.

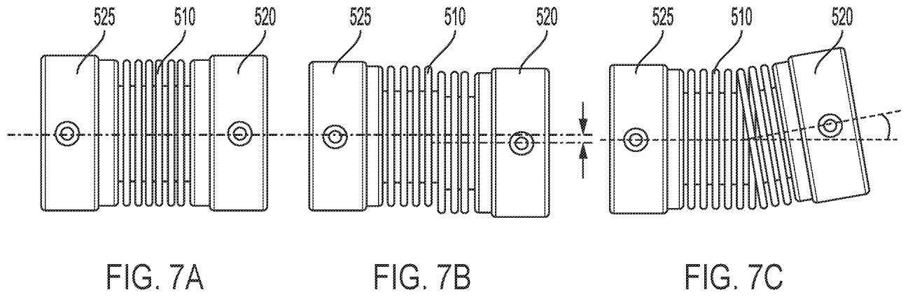

One advantage of a TWA 500 as described herein is that it provides all the DOFs needed to accommodate any type of assembly misalignment between the TWA and the component being adjusted inside of the optical module. Various types of misalignment are possible. For example, FIG. 7A depicts a case of axial misalignment in which the axis of rotation of the entire coupler 510 is displaced vertically in the figure. FIG. 7B depicts parallel misalignment in which an axis of rotation of a portion of the coupler 510 is displaced vertically with respect to the axis of rotation of the other portion of the coupler 510. FIG. 7C depicts angular misalignment in which the axis of rotation of a portion of the coupler 510 is at an angle with respect to the axis of rotation of the other portion of the coupler 510. A conventional TWA in general has difficulty accommodating these types of misalignment. The TWA 500 and the TSCE 480 described above, however, include bellows couplings which are torsionally stiff along their axis of rotation DOF (Rx) and flexible in the other five DOFs (three translational (X, Y, Z) and two rotational (Ry, Rz)). TWA 500 and the TSCE 480 can therefore accommodate some amount of axial, parallel, and angular misalignment while being torsionally stiff so they can transmit torque.

One challenge in the design of a TWA is gas and radiation leakage during optics alignment. The internal pressure in an optical module such as the optical pulse stretcher can be on the order of four to five PSI above atmospheric pressure. There is thus a pressure differential across the wall of the optical module tending to cause the purge gas inside the optical module (e.g., clean dry nitrogen) to escape the optical module. Another technical challenge in the design of a TWA is scattered radiation (DUV) leaking past any clearances between components.

To avoid these issues, according to an aspect of an embodiment the TWA is designed using a spherical bearing. A spherical bearing is made up of an outer ring and an inner ring and a locking feature that captures the inner ring within the outer ring in the axial direction only. The outer surface of the inner ring and the inner surface of the outer ring together make up the raceway as they slide past each other. The inner ring and the outer ring are precision fit to one another. In addition, the spherical bearing is secured using an interference fit into its position in the TWA. Nitrogen and radiation leakage and oxygen ingress are thus minimized due to the precision and interference fits between the components.

FIG. 8 is a cross section of a TWA 600 incorporating a spherical bearing according to an aspect of an embodiment. The TWA 600 of FIG. 8 includes many of the same components and having like reference numerals as the TWA 500 of FIGS. 5 and 6 except that the portion of the TWA 600 which extends out past the wall of the optical module includes the spherical bearing made up of an inner ring 620 and an outer ring 630. The inner ring 620 is convex having a contour curved like the exterior of a circle or sphere and the outer ring 630 is concave having a complementary contour that curves inward like the interior of a circle or sphere. As mentioned, these two components are precision fit to limit the amount of gas and/or radiation escaping from the optical module through the external projection of the TWA 600. In some embodiments the inner ring 620 is made of a carbon alloy bearing steel (e.g., AISI 52100). In some embodiments the outer ring is made of a phosphor bronze alloy (e.g., C52100). The use of these different and dissimilar alloys reduces the torque necessary to induce relative rotation of these components. This eliminates or minimizes actuation loads and thus the need for lubrication. It is also possible to use a ceramic inner ring made of a silicon nitride-alumina composite (Si₃N₄/Al₂O₃), or stainless steel such as AISI 420.

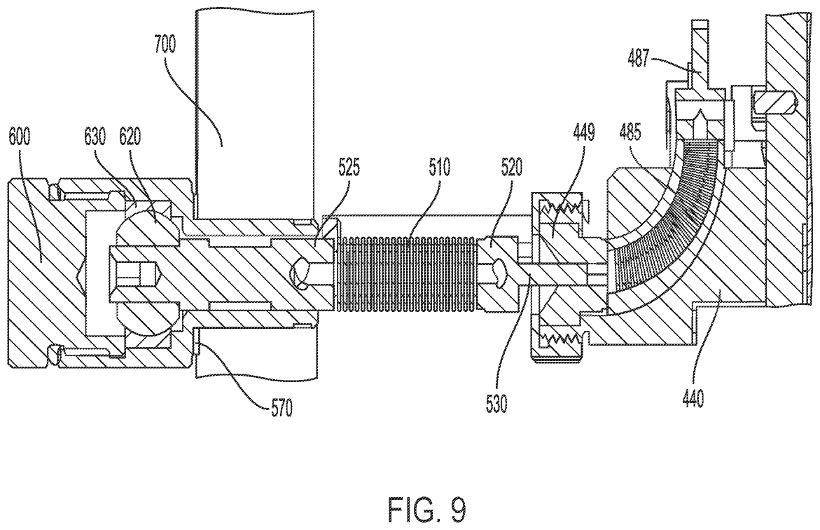

The embodiments of TWAs disclosed herein are useful in combination with various types of actuators within an optical module and are useful in particular with an actuator incorporating a curved corrugated coupler because such TWAs do not require or generate any axial translation in order to operate. FIG. 9 is a cross section of an arrangement for an adjuster using the coupler 600 of FIG. 8 in combination with an actuator incorporating a curved corrugated coupler as described above. As shown in FIG. 9, the overall arrangement includes the concertinaed coupling element 510 with end pieces 520 and 525. The arrangement also includes the end cap 600 including a spherical bearing made up of an inner ring 620 and an outer ring 630. Also shown is the seal 570. The endcap 600 permits access to a shaft 525 which extends through the wall 700 of an optical module. The projection 530 mates with the coupling member 449 of the actuator. The actuator includes a concertinaed element 485 and end fitting 487 which couples to a part within the optical module which it is desired to adjust. The concertinaed element 485 is disposed within a guide 440 as described above.

The above description includes examples of multiple embodiments. It is, of course, not possible to describe every conceivable combination of components or methodologies for purposes of describing the these embodiments, but one of ordinary skill in the art may recognize that many further combinations and permutations of various embodiments are possible. Accordingly, the described embodiments are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

The implementations can be further described using the following clauses.

1. An optical element alignment mechanism comprising:
a guide with an arcuate channel, the arcuate channel having a first channel end and a second channel end;
a torsionally stiff elongate member at least partially positioned in the arcuate channel and having an arcuate configuration conforming to an interior of the arcuate channel, the torsionally stiff elongate member having a first end rotatable in a first plane and a second end rotatable in a second plane substantially orthogonal to the first plane;
a first mechanical coupling member coupled to the first end; and
a second mechanical coupling member coupled to the second end;
whereby rotation of the first mechanical coupling member in the first plane causes rotation of the second coupling member in the second plane.
   2. The optical element alignment mechanism of clause 1 wherein the first mechanical coupling member comprises a receptacle member for torsional actuation.
   3. The optical element alignment mechanism of clause 1 wherein the second mechanical coupling member comprises a protrusion for torsional actuation.
   4. The optical alignment mechanism of clause 1 wherein the torsionally stiff elongate member comprises an electroformed bellows, wherein the bellows is flexible in degrees of freedom other than axial rotation.
   5. The optical alignment mechanism of clause 1 wherein the torsionally stiff elongate member comprises a high strength nickel alloy.
   6. The optical alignment mechanism of clause 5 wherein the nickel alloy includes copper.
   7. The optical alignment mechanism of clause 5 wherein the torsionally stiff elongate member comprises an electroformed plating.
   8. The optical alignment mechanism of clause 1 wherein the guide comprises leaded brass.
   9. The optical alignment mechanism of clause 1 wherein the guide comprises leaded bronze.
   10. The optical alignment mechanism of clause 1 wherein the guide comprises an alloy which is substantially free of lead.
   11. The optical alignment mechanism of clause 1 wherein the guide comprises a first material comprising a pure metal or metallic alloy and the first and second mechanical coupling members comprise a second material that is substantially dissimilar to the first material.
   12. The optical element alignment mechanism of clause 1 wherein the torsionally stiff elongate member has a substantially circular cross section and the arcuate channel has a substantially semicircular cross section.
   13. The optical element alignment mechanism of clause 1 wherein the torsionally stiff elongate member has a length in a range of about 15 mm to about 40 mm.
   14. The optical element alignment mechanism of clause 1 wherein the torsionally stiff elongate member has a diameter in a range of about 5 mm to about 10 mm.
   15. The optical element alignment mechanism of clause 1 wherein the torsionally stiff elongate member has a radius of curvature in a range of about 10 mm to about 25 mm.
   16. The optical element alignment mechanism of clause 1 wherein the arcuate channel is open along at least part of an arc length of the arcuate channel.
   17. A lithographic apparatus comprising:
an optical pulse stretcher including an enclosure adapted to contain a sealed and pressurized environment and including a wall, the wall having a through-the-wall adjuster;
an optical component positioned in the enclosure, at least one of a position and an orientation of the optical component being adjustable by application of a torque to the optical component in a first plane;
an elongate torsionally stiff torque transfer element positioned at least partially in the enclosure and having a first end mechanically coupled to the optical component and a second end mechanically coupled to the through-the-wall adjuster, wherein the elongate torsionally stiff torque transfer element is arranged so that rotation in a second plane by manipulation of the through-the-wall adjuster applies the torque to the optical component in the first plane, the first plane and the second plane being substantially orthogonal.
   18. The lithographic apparatus of clause 17 wherein the elongate torsionally stiff torque transfer element comprises an electroformed bellows.
   19. The lithographic apparatus of clause 17 wherein the elongate torsionally stiff torque transfer element comprises a bellows comprising a high strength nickel alloy.
   20. The lithographic apparatus of clause 17 further comprising a guide having an arcuate channel arranged to support and laterally stabilize the elongate torsionally stiff torque transfer element and wherein the elongate torsionally stiff torque transfer element comprises a nickel alloy and the guide comprises leaded brass or leaded bronze.
   21. The lithographic apparatus of clause 17 further comprising an arcuate channel arranged along at least part of a length of the elongate torsionally stiff torque transfer element to limit lateral movement or buckling of the elongate torsionally stiff torque transfer element.
   22. The lithographic apparatus of clause 21 wherein the arcuate channel has an open portion along at least part of the length of the arcuate channel.
   23. The lithographic apparatus of clause 21 wherein the arcuate channel and the torsionally stiff torque transfer element are dimensioned and arranged such that the arcuate channel does not mechanically contact the torsionally stiff torque transfer element along a concertinaed portion of the torsionally stiff torque transfer element.
   24. The lithographic apparatus of clause 21 wherein the elongate torsionally stiff torque transfer element has a substantially circular cross section and the arcuate channel has a substantially semicircular cross section with a nominal clearance to the circular cross section of the torsionally stiff torque transfer element.
   25. The lithographic apparatus of clause 17 wherein the elongate torsionally stiff torque transfer element has a length in a range of about 15 mm to about 40 mm.
   26. The lithographic apparatus of clause 17 wherein the elongate torsionally stiff torque transfer element has a length in a diameter of about 5 mm to about 10 mm.
   27. The lithographic apparatus of clause 17 wherein the elongate torsionally stiff torque transfer element has a radius of curvature in a range of about 10 mm to about 25 mm.
   28. The lithographic apparatus of clause 17 wherein the elongate torsionally stiff torque transfer element comprises a torsionally stiff elongate member partially positioned in a guide having an arcuate channel, the torsionally stiff elongate member positioned to conform to an interior of the arcuate channel, the torsionally stiff elongate member having a first end rotatable in the first plane and a second end rotatable in the second plane, the arcuate channel and the torsionally stiff elongate member being spaced apart by a clearance.
   29. The lithographic apparatus of clause 17 wherein the elongate torsionally stiff torque transfer element is substantially free of any lubricant.
   30. The lithographic apparatus of clause 17 wherein the elongate torsionally stiff torque transfer element contains only metallic or ceramic materials that will not contaminate the enclosure when the elongate torsionally stiff torque transfer element is exposed to scattered or direct deep ultraviolet radiation.
   31. The lithographic apparatus of clause 20 wherein the elongate torsionally stiff torque transfer element comprises a first material and the guide comprises a second material different from the first metal.
   32. Apparatus for adjusting an optical component in an optical module, the apparatus comprising a through-the-wall adjuster (TWA) comprising:
a concertinaed connecting element having a first end and a second end;
a first coupling element mechanically coupled to the first end, the first coupling element being adapted to impart a rotational force to adjust the optical component; and
a second coupling element mechanically coupled to the second end, the second coupling element having an external portion dimensioned and configured to extend to an exterior of the optical module and being externally accessible and rotatable to impart a rotational force to the concertinaed connecting element.
   33. The apparatus of clause 32 wherein the concertinaed connecting element comprises an electroformed bellows, wherein the bellows is flexible in all degrees of freedom other than axial rotation.
   34. The apparatus of clause 32 further comprising a spherical bearing arranged in the second coupling element to permit rotation of the second coupling element while sealing an interior of the optical module.
   35. The apparatus of clause 34 wherein the spherical bearing comprises a convex inner ring having a first contour and an outer ring with a concave inner surface having a second contour complementary to the first contour.
   36. The apparatus of clause 35 wherein the inner ring comprises a carbon alloy bearing steel.
   37. The apparatus of clause 35 wherein the inner ring comprises a ceramic material.
   38. The apparatus of clause 35 wherein the inner ring comprises a stainless steel.
   39. The apparatus of clause 35 wherein the inner ring comprises a silicon nitride-alumina composite material.
   40. The apparatus of clause 35 wherein the outer ring comprises a phosphor bronze alloy material.
   41. The apparatus of clause 32 further comprising an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator comprising a curved concertinaed coupling element having a first end adapted to rotate around the first axis and a second end adapted to rotate around the second axis.
   42. The apparatus of clause 41 wherein the curved concertinaed coupling element comprises an electroformed bellows, wherein the bellows is flexible in all degrees of freedom other than axial rotation.
   43. The apparatus of clause 32 further comprising an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator the actuator comprises a curved torsionally stiff elongate member positioned in an arcuate channel in a guide, the torsionally stiff elongate member having a first end rotatable around the first axis and a second end rotatable around the second axis, an interior of the arcuate channel and the torsionally stiff elongate member being spaced apart by a clearance.
   44. A lithographic apparatus comprising:
an optical pulse stretcher including an enclosure adapted to contain a sealed and pressurized environment and including a wall;
an optical component positioned in the enclosure, at least one of a position and an orientation of the optical component being adjustable by application of a torque to the optical component in a first plane; and
a through-the-wall adjuster (TWA) comprising
a concertinaed connecting element having a first end and a second end,
a first coupling element mechanically coupled to the first end, the first coupling element being adapted to impart a rotational force to adjust the optical component, and
a second coupling element mechanically coupled to the second end, the second coupling element having an external portion dimensioned and configured to extend to an exterior of the optical module and being externally accessible and rotatable to impart a rotational force to the concertinaed connecting element.
   45. The lithographic apparatus of clause 44 wherein the concertinaed connecting element comprises an electroformed bellows, wherein the bellows is flexible in all degrees of freedom other than axial rotation.
   46. The lithographic apparatus of clause 44 wherein the TWA further comprises a spherical bearing arranged in the second coupling element to permit rotation of the second coupling element while limiting an escape of gas and radiation from an interior of the optical module.
   47. The lithographic apparatus of clause 46 wherein the spherical bearing comprises a convex inner ring having a first contour and an outer ring with a concave inner surface having a second contour complementary to the first contour.
   48. The lithographic apparatus of clause 47 wherein the inner ring comprises a carbon alloy bearing steel.
   49. The lithographic apparatus of clause 47 wherein the inner ring comprises a ceramic material.
   50. The lithographic apparatus of clause 47 wherein the inner ring comprises stainless steel.
   51. The lithographic apparatus of clause 47 wherein the inner ring comprises a silicon nitride-alumina composite material.
   52. The lithographic apparatus of clause 47 wherein the outer ring comprises a phosphor bronze alloy material.
   53. The lithographic apparatus of clause 44 further comprising an actuator mechanically coupled to the TWA and to the optical component to convert a rotational force around a first axis from the TWA to a rotational force around a second axis and to couple the rotational force around the second axis to the optical component, the second axis being at an angle to the first axis, the actuator including a curved concertinaed coupling element having a first end adapted to rotate around the first axis and a second end adapted to rotate around the second axis.
   54. The lithographic apparatus of clause 53 wherein the actuator comprises a curved torsionally stiff elongate member positioned in an arcuate channel in a guide, the torsionally stiff elongate member having a first end rotatable around the first axis and a second end rotatable around the second axis, an interior of the arcuate channel and the torsionally stiff elongate member being spaced apart by a clearance.

The above described implementations and other implementations are within the scope of the following claims.

1. An optical element alignment mechanism comprising:
a guide with an arcuate channel, the arcuate channel having a first channel end and a second channel end;
a torsionally stiff elongate member at least partially positioned in the arcuate channel and having an arcuate configuration conforming to an interior of the arcuate channel, the torsionally stiff elongate member having a first end rotatable in a first plane and a second end rotatable in a second plane substantially orthogonal to the first plane;
a first mechanical coupling member coupled to the first end; and
a second mechanical coupling member coupled to the second end;
whereby rotation of the first mechanical coupling member in the first plane causes rotation of the second coupling member in the second plane.

2. The optical element alignment mechanism of claim 1 wherein the first mechanical coupling member comprises a receptacle member for torsional actuation.

3. The optical element alignment mechanism of claim 1 wherein the second mechanical coupling member comprises a protrusion for torsional actuation.

4. The optical alignment mechanism of claim 1 wherein the torsionally stiff elongate member comprises an electroformed bellows, wherein the bellows is flexible in degrees of freedom other than axial rotation.

5. The optical alignment mechanism of claim 1 wherein the torsionally stiff elongate member comprises a high strength nickel alloy.

6. The optical alignment mechanism of claim 5 wherein the nickel alloy includes copper.

7. The optical alignment mechanism of claim 5 wherein the torsionally stiff elongate member comprises an electroformed plating.

8. The optical alignment mechanism of claim 1 wherein the guide comprises leaded brass.

9. The optical alignment mechanism of claim 1 wherein the guide comprises leaded bronze.

10. The optical alignment mechanism of claim 1 wherein the guide comprises an alloy which is substantially free of lead.

11. The optical alignment mechanism of claim 1 wherein the guide comprises a first material comprising a pure metal or metallic alloy and the first and second mechanical coupling members comprise a second material that is substantially dissimilar to the first material.

12. The optical element alignment mechanism of claim 1 wherein the torsionally stiff elongate member has a substantially circular cross section and the arcuate channel has a substantially semicircular cross section.

13. The optical element alignment mechanism of claim 1 wherein the torsionally stiff elongate member has a length in a range of about 15 mm to about 40 mm.

14. The optical element alignment mechanism of claim 1 wherein the torsionally stiff elongate member has a diameter in a range of about 5 mm to about 10 mm.

15. The optical element alignment mechanism of claim 1 wherein the torsionally stiff elongate member has a radius of curvature in a range of about 10 mm to about 25 mm.

16. The optical element alignment mechanism of claim 1 wherein the arcuate channel is open along at least part of an arc length of the arcuate channel.

17. A lithographic apparatus comprising:
an optical pulse stretcher including an enclosure adapted to contain a sealed and pressurized environment and including a wall, the wall having a through-the-wall adjuster;
an optical component positioned in the enclosure, at least one of a position and an orientation of the optical component being adjustable by application of a torque to the optical component in a first plane;
an elongate torsionally stiff torque transfer element positioned at least partially in the enclosure and having a first end mechanically coupled to the optical component and a second end mechanically coupled to the through-the-wall adjuster, wherein the elongate torsionally stiff torque transfer element is arranged so that rotation in a second plane by manipulation of the through-the-wall adjuster applies the torque to the optical component in the first plane, the first plane and the second plane being substantially orthogonal.

18. The lithographic apparatus of claim 17 wherein the elongate torsionally stiff torque transfer element comprises an electroformed bellows.

19. The lithographic apparatus of claim 17 wherein the elongate torsionally stiff torque transfer element comprises a bellows comprising a high strength nickel alloy.

20. The lithographic apparatus of claim 17 further comprising a guide having an arcuate channel arranged to support and laterally stabilize the elongate torsionally stiff torque transfer element and wherein the elongate torsionally stiff torque transfer element comprises a nickel alloy and the guide comprises leaded brass or leaded bronze.

21. The lithographic apparatus of claim 17 further comprising an arcuate channel arranged along at least part of a length of the elongate torsionally stiff torque transfer element to limit lateral movement or buckling of the elongate torsionally stiff torque transfer element.

22. The lithographic apparatus of claim 21 wherein the arcuate channel has an open portion along at least part of the length of the arcuate channel.

23. The lithographic apparatus of claim 21 wherein the arcuate channel and the torsionally stiff torque transfer element are dimensioned and arranged such that the arcuate channel does not mechanically contact the torsionally stiff torque transfer element along a concertinaed portion of the torsionally stiff torque transfer element.

24. The lithographic apparatus of claim 21 wherein the elongate torsionally stiff torque transfer element has a substantially circular cross section and the arcuate channel has a substantially semicircular cross section with a nominal clearance to the circular cross section of the torsionally stiff torque transfer element.

25. The lithographic apparatus of claim 17 wherein the elongate torsionally stiff torque transfer element has a length in a range of about 15 mm to about 40 mm.

26. The lithographic apparatus of claim 17 wherein the elongate torsionally stiff torque transfer element has a length in a diameter of about 5 mm to about 10 mm.

27. The lithographic apparatus of claim 17 wherein the elongate torsionally stiff torque transfer element has a radius of curvature in a range of about 10 mm to about 25 mm.

28. The lithographic apparatus of claim 17 wherein the elongate torsionally stiff torque transfer element comprises a torsionally stiff elongate member partially positioned in a guide having an arcuate channel, the torsionally stiff elongate member positioned to conform to an interior of the arcuate channel, the torsionally stiff elongate member having a first end rotatable in the first plane and a second end rotatable in the second plane, the arcuate channel and the torsionally stiff elongate member being spaced apart by a clearance.

29. The lithographic apparatus of claim 17 wherein the elongate torsionally stiff torque transfer element is substantially free of any lubricant.

30. The lithographic apparatus of claim 17 wherein the elongate torsionally stiff torque transfer element contains only metallic or ceramic materials that will not contaminate the enclosure when the elongate torsionally stiff torque transfer element is exposed to scattered or direct deep ultraviolet radiation.

31. The lithographic apparatus of claim 20 wherein the elongate torsionally stiff torque transfer element comprises a first material and the guide comprises a second material different from the first metal.

32.-54. (canceled)
